(19) United States
(12) Patent Application Publication
(10) Pub. No.: US 2025/0261519 A1
(43) Pub. Date: Aug. 14, 2025

(54) MULTILAYER OVERHANG ROOF FOR OLED SUB-PIXEL CIRCUIT

(71) Applicant: Applied Materials, Inc., Santa Clara, CA (US)

(72) Inventors: Jungmin LEE, Santa Clara, CA (US); Dieter HAAS, Santa Clara, CA (US); Gregory Max MCDANIEL, San Jose, CA (US); Yu-Hsin LIN, Zhubei City (TW)

(21) Appl. No.: 19/040,816

(22) Filed: Jan. 29, 2025

Related U.S. Application Data
(60) Provisional application No. 63/553,213, filed on Feb. 14, 2024.

(51) Int. Cl. H10K 59/122; H10K 59/12

(52) U.S. Cl. CPC H10K 59/122; H10K 59/1201

(57) ABSTRACT

Embodiments described herein relate to sub-pixel circuits and methods of forming sub-pixel circuits that may be utilized in a display such as an organic light-emitting diode (OLED) display. A method of forming a sub-pixel circuit includes depositing an anode over a substrate; depositing a pixel isolation structures (PIS) layer over the substrate; removing one or more portions of the PIS layer to form a plurality of first PIS and second PIS; planarizing the first PIS and the second PIS; depositing a first structure layer, a first metal-containing layer of a second structure layer, and a second metal-containing layer of the second structure layer over the substrate; disposing and patterning a first resist over the second structure layer; and removing portions of the second structure layer to form a second structure and portions of the first structure layer to form a first structure.

### CROSS-REFERENCE TO RELATED APPLICATIONS

This application claims priority to U.S. Provisional Patent Application Ser. No. 63/553,213, filed on Feb. 14, 2024, which is herein incorporated by reference.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

Some techniques for OLED manufacturing result in delamination between dies and upper layers of the display. Accordingly, what is needed in the art are sub-pixel circuits and methods of forming sub-pixel circuits to prevent the delamination and provide improved yields in OLED manufacturing.

### SUMMARY

In one embodiment, a sub-pixel is provided. The sub-pixel includes adjacent overhang structures disposed over a substrate, wherein the overhang structures comprise: a second structure disposed over a first structure, wherein the second structure includes a second metal-containing layer disposed over a first metal-containing layer, the second structure including a bottom surface having a second width that is greater than a first width of a top surface of the first structure; an organic light emitting (OLE) material disposed between the adjacent overhang structures; and a cathode disposed over the OLE material between the adjacent overhang structures.

In another embodiment, a sub-pixel circuit is disclosed. The sub-pixel circuit includes a plurality of overhang structures disposed over a substrate, wherein adjacent overhang structures of the plurality of overhang structures define sub-pixels, each sub-pixel comprising: the adjacent overhang structures, wherein each overhang structure comprises a second structure disposed over a first structure, wherein the second structure includes a second metal-containing layer disposed over a first metal-containing layer, the second structure including a bottom surface having a second width that is greater than a first width of a top surface of the first structure; an organic light emitting (OLE) material disposed between the adjacent overhang structures; and a cathode disposed over the OLE material between the adjacent overhang structures.

In another embodiment, a method of forming a sub-pixel circuit is disclosed. The method includes depositing an anode over a substrate; depositing a pixel isolation structure (PIS) layer over the substrate; removing one or more portions of the PIS layer to form a plurality of first PIS and second PIS; planarizing the first PIS and the second PIS; depositing a first structure layer, a first metal-containing layer of a second structure layer, and a second metal-containing layer of the second structure layer over the substrate; disposing and patterning a first resist over the second structure layer; and removing portions of the second structure layer to form a second structure and portions of the first structure layer to form a first structure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit having a second structure with two layers at section line 1A-1A of FIG. 1D according to embodiments.

FIG. 1B is a schematic, cross-sectional view of a sub-pixel circuit having a second structure with two layers at section line 1A-1A of FIG. 1D according to embodiments.

FIG. 1C is a schematic, cross-sectional view of a sub-pixel circuit at section line 1B-1B of FIG. 1D according to embodiments.

FIG. 1D is a schematic, cross-sectional view of a sub-pixel circuit having a line-type architecture at section line 1C-1C of FIG. 1A according to embodiments.

FIG. 2 is a schematic, cross-sectional view of an overhang structure according to embodiments.

FIG. 3A is a schematic, cross-sectional view of a sub-pixel circuit having a second structure that has two layers, according to embodiments.

FIG. 3B is a schematic, cross-sectional view of a sub-pixel circuit having a second structure that has three layers, according to embodiments.

FIG. 4 is a flow diagram of a method for forming a sub-pixel circuit according to according to embodiments.

FIGS. 5A-5H are schematic, cross-sectional views of a substrate during a method of forming a sub-pixel according to embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In various embodiments, the sub-pixels employ overhang structures having multiple layers to improve functionality of the display.

Each of the embodiments described herein of the sub-pixel circuit include a plurality of sub-pixels with each of the sub-pixels are defined by adjacent overhang structures that are permanent to the sub-pixel circuit. While the Figures depict two sub-pixels with each sub-pixel defined by adjacent overhang structures, the sub-pixel circuit of the embodiments described herein include a plurality of sub-pixels, such as two or more subpixels. Each sub-pixel has OLE materials configured to emit a white, red, green, blue, or other color light when energized. E.g., the OLE materials of a first sub-pixel emits a red light when energized, the OLE materials of a second sub-pixel emits a green light when energized, and the OLE materials of a third sub-pixel emits a blue light when energized.

The overhangs are permanent to the sub-pixel circuit and include at least a second structure disposed over a first structure. The adjacent overhang structures defining each sub-pixel of the sub-pixel circuit of the display provide for formation of the sub-pixel circuit using evaporation deposition and provide for the overhang structures to remain in place after the sub-pixel circuit is formed. Evaporation deposition is utilized for deposition of OLE materials (including a hole injection layer (HIL), a hole transport layer (HTL), an emissive layer (EML), and an electron transport layer (ETL)) and cathode. In some instances, an encapsulation layer may be disposed via evaporation deposition. In embodiments including one or more capping layers, the capping layers are disposed between the cathode and the encapsulation layer. The overhang structures and the evaporation angle set by the evaporation source define the deposition angles, i.e., the overhang structures provide for a shadowing effect during evaporation deposition with the evaporation angle set by the evaporation source. In order to deposit at a particular angle, the evaporation source is configured to emit the deposition material at a particular angle with regard to the overhang structure. The encapsulation layer of a respective subpixel is disposed over the cathode with the encapsulation layer extending under at least a portion of each of the adjacent overhang structures and along a sidewall of each of the adjacent overhang structures.

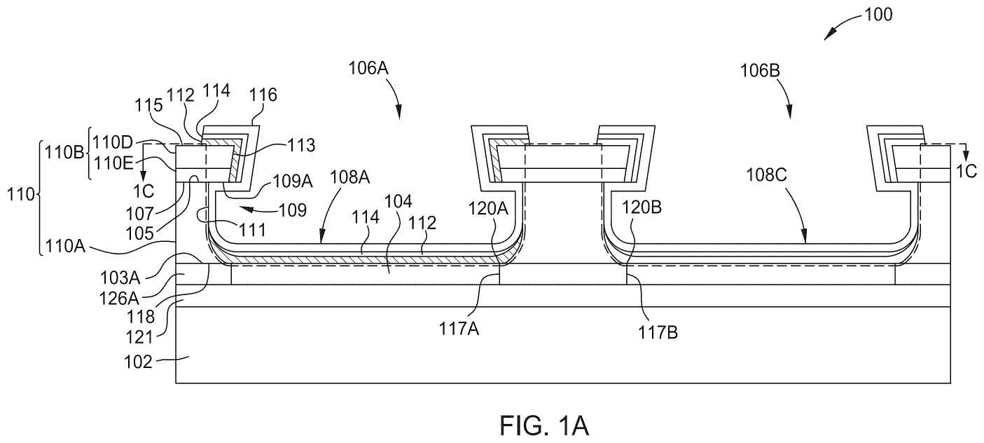

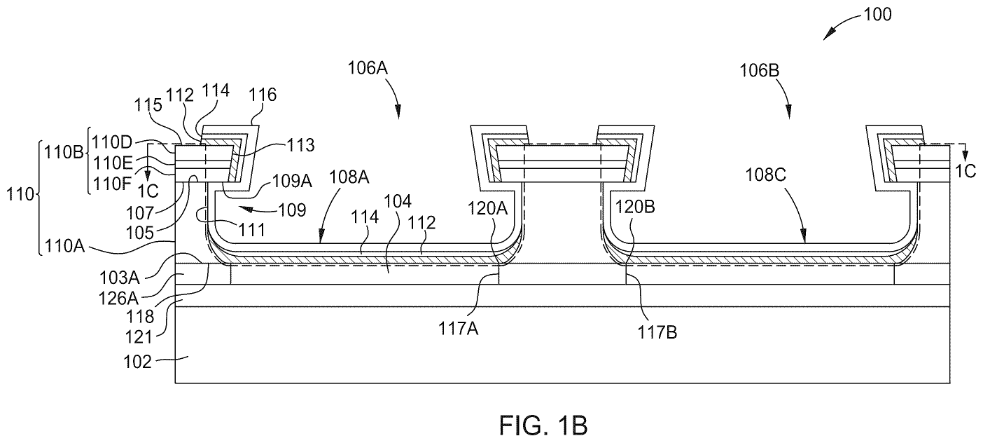

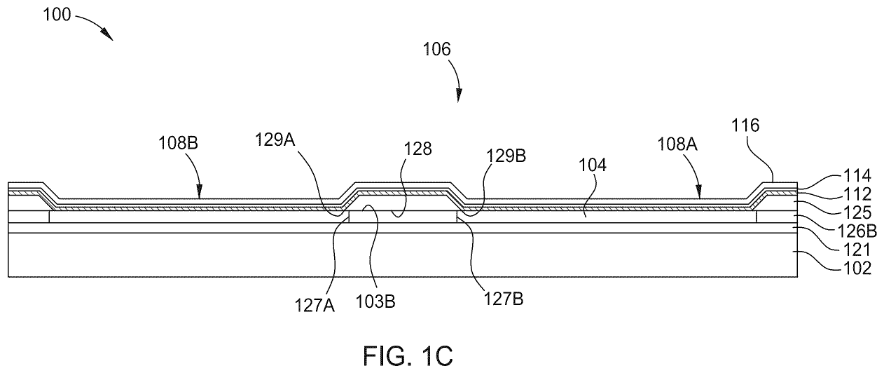

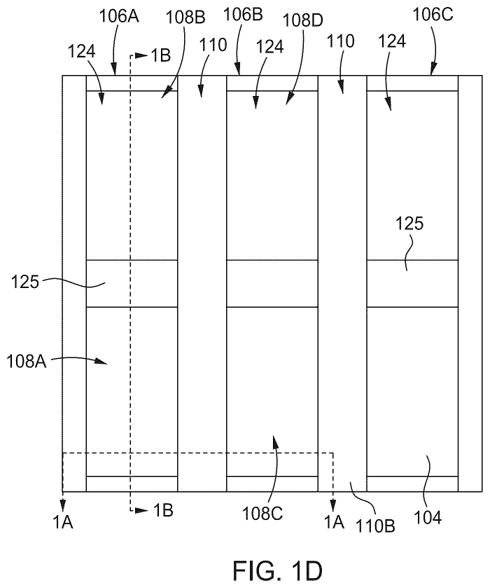

FIG. 1A is a schematic, cross-sectional view of a sub-pixel circuit 100 according to embodiments. The cross-sectional view of FIG. 1A is taken along section line 1A-1A of FIG. 1D (e.g., a pixel plane). FIG. 1C is a schematic, cross-sectional view of a sub-pixel circuit 100 according to embodiments. The cross-sectional view of FIG. 1C is taken along section line 1B-1B of FIG. 1D (e.g., a line plane). The sub-pixel circuit 100 includes a substrate 102. A base layer 121 may be patterned over the substrate 102. The base layer 121 includes, but is not limited to, a CMOS layer. The base layer 121 is operable to function as a CMOS layer. Metal-containing layers (e.g., anodes 104) may be patterned on the base layer 121 and are defined by adjacent first pixel isolation structures (PIS) 126A and second PIS 126B disposed on the substrate 102. In one embodiment, the anodes 104 are pre-patterned on the base layer 121. E.g., the base layer 121 is pre-patterned with anodes 104 of indium tin oxide (ITO). The anodes 104 may be disposed on the substrate 102. The anodes 104 are configured to operate as anodes of respective sub-pixels. In one embodiment, the anode 104 is a layer stack of a first transparent conductive oxide (TCO) layer, a second metal-containing layer disposed on the first TCO layer, and a third TCO layer disposed on the second metal-containing layer. The anodes 104 include, but are not limited to, chromium, titanium, gold, silver, copper, aluminum, ITO, a combination thereof, or other suitably conductive materials.

The first PIS 126A and second PIS 126B are disposed over the substrate 102. The first PIS 126A and second PIS 126B may be disposed on the base layer 121. The first PIS 126A is disposed along the line plane. The line plane extends along a first direction. The second PIS 126B is disposed along the pixel plane. The pixel plane extends along a second direction. The first direction is perpendicular to the second direction. The first PIS 126A and second PIS 126B include one of an organic material, an organic material with an inorganic coating disposed thereover, or an inorganic material. The organic material of the first PIS 126A and second PIS 126B includes, but is not limited to, polyimides. The inorganic material of the first PIS 126A and second PIS 126B includes, but is not limited to, silicon oxide (SiO₂), silicon nitride (Si₃N₄), silicon oxynitride (Si₂N₂O), magnesium fluoride (MgF₂), or combinations thereof. Adjacent first PIS 126A and second PIS 126B define a respective sub-pixel and expose the anode 104 of the respective sub-pixel circuit 100.

The sub-pixel circuit 100 has a plurality of sub-pixel lines (e.g., first sub-pixel line 106A and second sub-pixel line 106B). The sub-pixel lines are adjacent to each other along the pixel plane. Each sub-pixel line includes at least two sub-pixels. E.g., the first sub-pixel line 106A includes a first sub-pixel 108A and a second sub-pixel 108B and the second sub-pixel line 106B includes a third sub-pixel 108C and a fourth sub-pixel 108D. The first sub-pixel 108A and the second sub-pixel 108B are aligned along the line plane. The third sub-pixel 108C and the fourth sub-pixel 108D are aligned along the line plane. While FIG. 1A depicts the first sub-pixel line 106A and the second sub-pixel line 106B, the sub-pixel circuit 100 of the embodiments described herein may include two or more sub-pixel lines, such as a third sub-pixel line 106C (as shown in FIG. 1C) and a fourth sub-pixel. Each sub-pixel line has OLE materials configured to emit a white, red, green, blue, or other color light when energized. E.g., the OLE materials of the first sub-pixel line 106A emits a red light when energized, the OLE materials of the second sub-pixel line 106B emits a green light when energized, the OLE materials of a third sub-pixel line 106C emits a blue light when energized, and the OLE materials of a fourth sub-pixel emits another color light when energized. The OLE materials within a pixel line may be configured to emit the same color light when energized. E.g., the OLE materials of the first sub-pixel 108A and the second sub-pixel 108B of the first sub-pixel line 106A emit a red light when energized and the OLE materials of the third sub-pixel 108C and the fourth sub-pixel 108D of the second sub-pixel line 106B emit a green light when energized.

Each sub-pixel line includes adjacent overhang structures 110, with adjacent sub-pixel lines sharing the adjacent overhang structures 110 in the pixel plane. The overhang structures 110 are permanent to the sub-pixel circuit 100. The overhang structures 110 further define each sub-pixel line of the sub-pixel circuit 100. Each overhang structure 110 includes adjacent overhangs 109. The adjacent overhangs 109 are defined by an overhang extension 109A of a second structure 110B extending laterally past an upper surface 105 of a first structure 110A. The first structure 110A is disposed over an upper surface 103A of the first PIS 126A. A first endpoint 120A of a bottom surface 118 of the first structure 110A may extend to or past a first edge 117A of the first PIS 126A. A second endpoint 120B of the bottom surface of the first structure 110A may extend to or past a second edge 117B the first PIS 126A. The second structure 110B is disposed over the first structure 110A. The second structure 110B may be disposed on the upper surface 105 of the first structure 110A.

The adjacent overhangs 109 are defined by the overhang extension 109A. At least a bottom surface 107 of the second structure 110B is wider than the upper surface 105 of the first structure 110A to form the overhang extension 109A. The overhang extension 109A of the second structure 110B forms the overhang 109 and allows for the second structure 110B to shadow the first structure 110A. The shadowing of the overhang 109 provides for evaporation deposition of an OLE material 112 and a cathode 114.

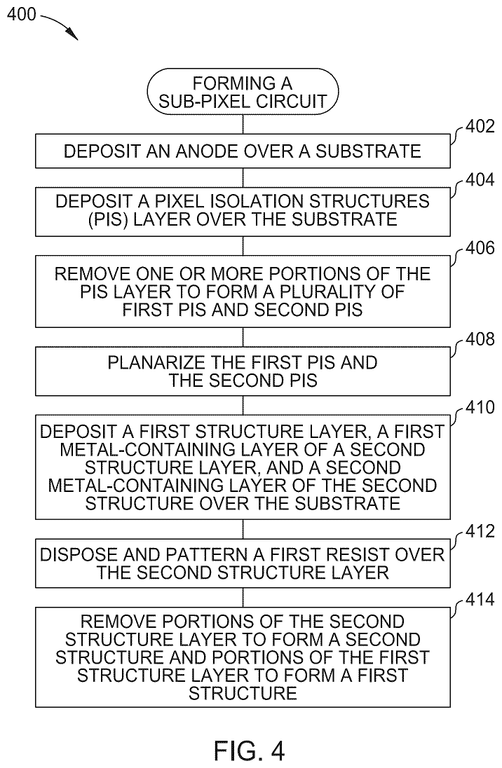

The second structure 110B may be formed from two or more metal-containing layers 110D, 110E, etc., as illustrated in more detail in FIGS. 4A and 4B. The two or more layers 110D, 110E, etc. may include chromium (Cr), titanium (Ti), or chromium oxide (Cr₂O₃), for example. In embodiments of the present disclosure, a first metal-containing layer 110E may be considered stress-relieving and may improve adhesion of the second structure 110B to the first structure 110A by opposing residual tensile stress in a second metal-containing layer 110D. In embodiments of the present disclosure, the second metal-containing layer 110D may be disposed over the first metal-containing layer 110E and may be suitable for selective etching. The second metal-containing layer 110D may include chromium, for example. The first metal-containing layer 110E may include titanium or chromium oxide, for example.

FIG. 1B is a schematic, cross-sectional view of a sub-pixel circuit 100 having a second structure 110B formed from three metal-containing layers 110D, 110E, and 110F, according to embodiments. The cross-sectional view of FIG. 1B is taken along section line 1A-1A of FIG. 1D (e.g., a pixel plane). In embodiments of the present disclosure, a third metal-containing layer 110F may be disposed over the first structure 110A. The third metal-containing layer 110F may include chromium, for example. In embodiments of the present disclosure, a first metal-containing layer 110E may be considered stress-relieving and may improve adhesion of the second structure 110B to the first structure 110A by opposing residual tensile stress in the third metal-containing layer 110F and a second metal-containing layer 110D. The first metal-containing layer 110E may be disposed over the third metal-containing layer 110F. The second metal-containing layer 110D may be disposed over the first metal-containing layer 110E and may be suitable for selective etching. The second metal-containing layer 110D may include chromium, for example. The first metal-containing layer 110E may include titanium or chromium oxide, for example. Other components shown in FIG. 1B are described with reference to FIG. 1A and are not further described herein.

Returning to FIG. 1A, the OLE material 112 may include one or more of a HIL, a HTL, an EML, and an ETL. The OLE material 112 is disposed over and in contact with the anode 104. The OLE material 112 is disposed under adjacent overhangs 109 and may contact a sidewall 111 of the first structure 110A. In one embodiment, the OLE material 112 is different from the materials of the first structure 110A and the second structure 110B. The cathode 114 is disposed over the OLE material 112 and extends under the adjacent overhangs 109. The cathode 114 may extend past an endpoint of the OLE material 112. The cathode 114 may contact the sidewall 111 of the first structure 110A. The overhang structures 110 and an evaporation angle set by an evaporation source define deposition angles, i.e., the overhang structures provide for a shadowing effect during evaporation deposition with the evaporation angle set by the evaporation source.

The cathode 114 includes a conductive material, such as a metal. E.g., the cathode 114 includes, but is not limited to, silver, magnesium, chromium, titanium, aluminum, ITO, or a combination thereof. In one embodiment, material of the cathode 114 is different from the material of the first structure 110A and the second structure 110B. In some embodiments, e.g., as shown in FIGS. 1A as applied to the sub-pixel circuit 100, the OLE material 112 and the cathode 114 are disposed over a sidewall 113 of the second structure 110B of the overhang structures 110 in the pixel plane. In other embodiments, the OLE material 112 and the cathode 114 are disposed over an upper surface 115 of the second structure 110B of the overhang structures 110 in the pixel plane. In still other embodiments, the OLE material 112 and the cathode 114 end on the sidewall 111 of the first structure 110A, i.e., are not disposed over the sidewall 113 of the second structure 110B or the upper surface 115 of the second structure 110B in the pixel plane.

Each sub-pixel 106 includes an encapsulation layer 116. The encapsulation layer 116 may be or may correspond to a local passivation layer. The encapsulation layer 116 of a respective sub-pixel is disposed over the cathode 114 (and OLE material 112) with the encapsulation layer 116 extending under at least a portion of each of the overhangs 109 and along a sidewall 111 of each of the first structure 110A and the second structure 110B. The encapsulation layer 116 is disposed over the cathode 114 and extends at least to contact the cathode 114 over the sidewall 111 of the first structure 110A in the pixel plane. In some embodiments, the encapsulation layer 116 extends to contact the sidewall 111 of the first structure 110A. In the illustrated embodiments as shown in FIGS. 1A, 1B, and 1C, the encapsulation layer 116 extends to contact the second structure 110B at an underside surface of the overhang extension 109A, the sidewall 113 of the second structure 110B, and the upper surface 115 of the second structure 110B. In some embodiments, the encapsulation layer 116 extends to contact the second structure 110B at an underside surface of the overhang extension 109A and to be disposed over the OLE material 112 and the cathode 114 when the OLE material 112 and the cathode 114 are disposed over the sidewall 113 and upper surface 115 of the second structure 110B. In some embodiments, the encapsulation layer 116 ends at the sidewall 111 of the first structure 110A, i.e., is not disposed over the sidewall 113 of the second structure 110B, the upper surface 115 of the second structure 110B, or the underside surface of the overhang extension 109A of the overhang structures 110. The encapsulation layer 116 includes the non-conductive inorganic material, such as the silicon-containing material. The silicon-containing material may include Si₃N₄ containing materials.

Each sub-pixel line includes adjacent separation structures 125, with adjacent sub-pixels sharing the adjacent separation structures 125 in the line plane. The separation structures 125 are permanent to the sub-pixel circuit 100. The separation structures 125 further define each sub-pixel of the sub-pixel line of the sub-pixel circuit 100. The separation structures 125 are disposed over an upper surface 103B of the second PIS 126B. A first endpoint 129A of a bottom surface 128 of the separation structures 125 may extend to or past a first edge 127A of the second PIS 126B. A second endpoint 129B of the bottom surface 128 of the separation structures 125 may extend to or past a second edge 127B the second PIS 126B.

The OLE material 112 is disposed over and in contact with the anode 104 and the separation structure 125 in the line plane. The cathode 114 is disposed over the OLE material 112 in the line plane. The encapsulation layer 116 is disposed over the cathode 114 in the line plane. As shown in FIG. 1C, the OLE material 112, the cathode 114, and the encapsulation layer 116 maintain continuity along the length of the line plane in order to apply current across each sub-pixel 106.

In embodiments including one or more capping layers, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition. In another embodiment, the sub-pixel circuit 100 further includes at least a global passivation layer disposed over the overhang structure 110 and the encapsulation layer 116. In yet another embodiment, the sub-pixel includes an intermediate passivation layer disposed over the overhang structures 110 of each of the sub-pixels 106, and disposed between the encapsulation layer 116 and the global passivation layer.

FIG. 1D is a schematic, cross-sectional view of a sub-pixel circuit 100 having a line-type architecture according to embodiments. The top sectional views of FIG. 1D is taken along section line 1C-1C of FIG. 1A. The line-type architecture includes a plurality of pixel openings 124. Each of pixel opening 124 is abutted by overhang structures 110 in the pixel plane and separation structure 125 in the line plane, as shown in FIG. 1A and FIG. 1C, which define each of the sub-pixel line and sub-pixel of the line-type architecture.

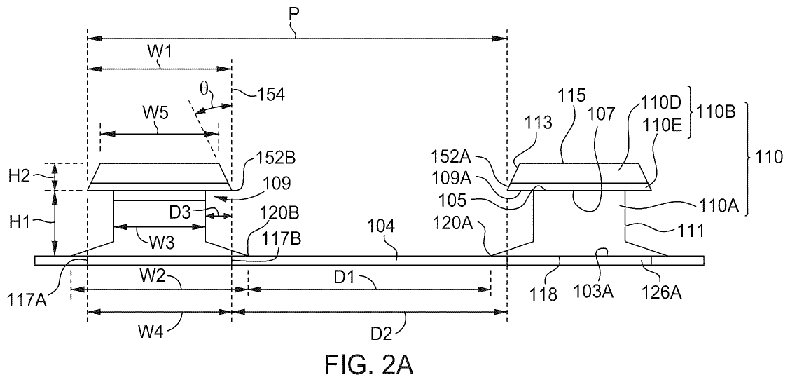

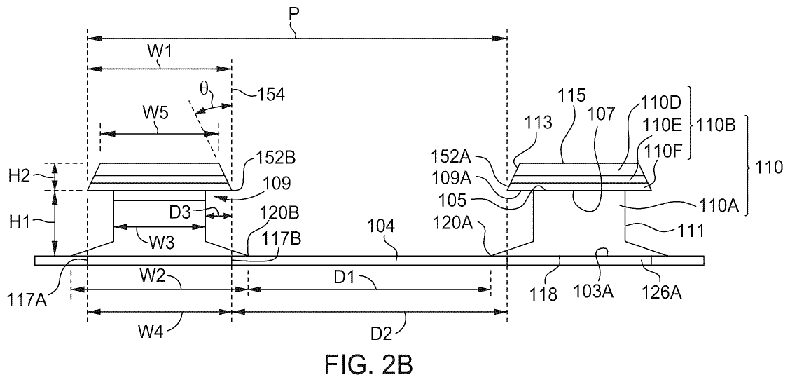

FIG. 2A is a schematic, cross-sectional view of an overhang structure 110. The overhang structure 110 is shown without the OLE material 112, the cathode 114, the encapsulation layer 116, the base layer 121, or the substrate 102. The second structure 110B includes at least a first layer 110E and a second layer 110D. The upper surface 115 of the second structure 110B has a width W1 from a first underside edge 152A to a second underside edge 152B. The width W1 is from about 0.4 μm to about 1.2 μm. The bottom surface 118 of the first structure 110A has a width W2 from the first endpoint 120A of the bottom surface 118 to the second endpoint 120B of the bottom surface 118. The width W2 is from about 0.6 μm to about 1.4 μm. The upper surface 105 of the first structure 110A has a width W3. The width W3 is from 0.2 μm to about 0.8 μm. The first PIS 126A has a width W4 from the first edge 117A to the second edge 117B. The width W4 is from 0.4 μm to about 1.2 μm. The width W4 and the width W1 may be equal or approximately equal. The upper surface 115 of the second structure 110B has a width W5. The width W5 is from about 0.2 μm to about 1.0 μm.

The overhang structures 110 has a height H1 from the upper surface 103A of the first PIS 126A to the bottom surface 107 of the second structure 110B. The height H1 is from about 0.1 μm to about 0.5 μm. The height H1 may be the height of the first structure 110A. The second structure 110B has a height H2 from the bottom surface 107 to the upper surface 115. The height H2 is from about 0.15 μm to about 0.25 μm. A width of the upper surface 115 of the second structure 110B is less than the width of the bottom surface 107 of the second structure 110B. The sidewall 113 of the second structure 110B has an angle θ with respect to an overhang vector 154 of about 15° to about 45°.

The sub-pixel circuit 100 has a pitch p. The pitch p is the distance from a first edge 117A of the first PIS 126A to the first edge 117A of an adjacent first PIS 126A. The pitch p is from about 2 μm to about 8 μm. The sub-pixel circuit 100 has a distance D1 from the second endpoint 120B of the first structure 110A of an overhang structure 110 to a first endpoint 120A of the first structure 110A of an adjacent overhang structure 110. The distance D1 is from about 2 μm to about 6 μm. The sub-pixel circuit 100 has a distance D2 from the second edge 117B of the first PIS 126A to the first edge 117A of the first PIS 126A of an adjacent overhang structure 110 (e.g., a width of the anode 104). The distance D2 is from 2 μm to about 6 μm. The distance D1 and the distance D2 may be equal or approximately equal. The overhang structure 110 has a distance D3 from a first underside edge 152A or a second underside edge 152B of the second structure 110B to the sidewall 111 of the first structure 110A. The distance D3 is less than about 0.15 μm.

FIG. 2B is a schematic, cross-sectional view of a sub-pixel circuit 100 having a second structure 110B formed from three layers 110D, 110E, and 110F, according to embodiments. The first layer 110E may include titanium or chromium oxide, for example. The second layer 110D may include chromium, for example. The third layer 110F may include chromium, for example. Other components shown in FIG. 2B are described with reference to FIG. 2A and are not further described herein.

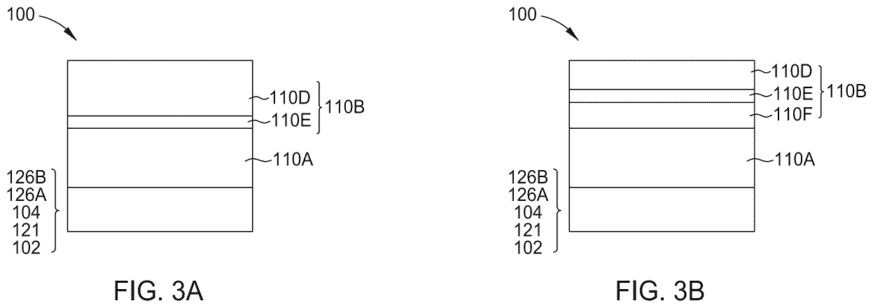

FIG. 3 is a schematic, cross-sectional view of a sub-pixel circuit 100 having a second structure 110B that has a single layer, according to embodiments of the present disclosure. Substrate 102, base layer 121, anodes 104, first sub-pixel 108A, and second sub-pixel 108B are described with reference to FIGS. 1A-1D and are not further described. The single layer of second structure 110B may include chromium, for example.

there is a potential for delamination to occur between first structures 110A, which may be amorphous silicon (a-Si), and first pixel isolation structure 126A or second pixel isolation structure 126B. It is believed that residual tensile stress in the single layer of second structure 110B is a cause of the potential delamination between first structures 110A and first pixel isolation structure 126A or second pixel isolation structure 126B. According to embodiments of the present disclosure, use of additional layers including other materials, for example titanium or chromium oxide, in the second structures 110B may reduce the potential delamination. The materials of the additional layers may be selected to have residual compressive stress that may oppose residual tensile stress in the second layer 110D of a second structure 110B having multiple layers, as described herein.

FIG. 3A is a schematic, cross-sectional view of a sub-pixel circuit 100 having a second structure 110B that has two layers 110D and 110E, according to embodiments of the present disclosure. Substrate 102, base layer 121, and anodes 104 are described with reference to FIGS. 1A-1D and are not further described. The second layer 110D of second structure 110B may be 100 nanometers (nm) to 200 nm thick and may include chromium, for example. The first layer 110E of second structure 110B may be 15 nm to 25 nm thick and may include titanium or chromium oxide, for example.

FIG. 3B is a schematic, cross-sectional view of a sub-pixel circuit 100 having a second structure 110B that has three layers 110D, 110E, and 110F, according to embodiments of the present disclosure. Substrate 102, base layer 121, and anodes 104 are described with reference to FIGS. 1A-1D and are not further described. The second layer 110D of second structure 110B may be 100 nm to 200 nm thick and may include chromium, for example. The first layer 110E of second structure 110B may be 15 nm to 25 nm thick and may include titanium or chromium oxide, for example. A third layer 110F of second structure 110B may be 100 nm to 200 nm thick and may include chromium, for example. While FIG. 4B illustrates a second structure 110B that has three layers, the present disclosure is not limited to three layers, and second structures 110B having more than three layers are contemplated in this disclosure.

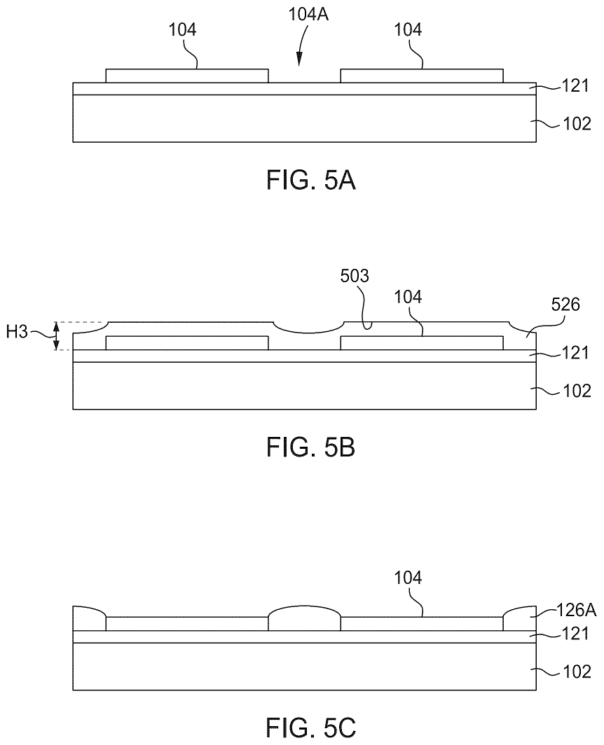

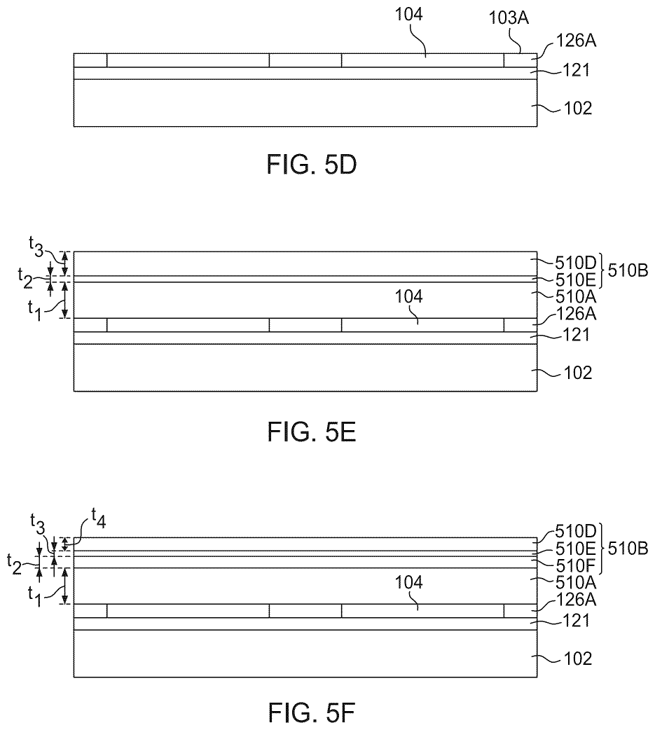

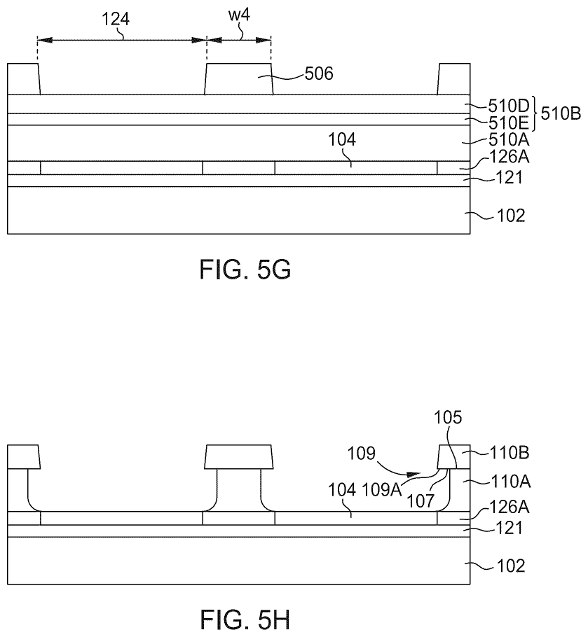

FIG. 4 is a flow diagram of a method 400 for forming a sub-pixel circuit 100, according to an embodiment. FIGS. 5A-5H are schematic, cross-sectional views of a substrate 102 during the method 400 for forming the sub-pixel circuit 100 according to embodiments described herein.

At operation 402, as shown in FIG. 5A (along the pixel plane), an anode 104 is deposited over the substrate 102. The anode 104 may be deposited on the substrate 102. In another embodiment, the anode 104 is deposited on a base layer 121. The base layer 121 is disposed on the substrate 102. In one embodiment, the base layer 121 may be pre-patterned over the substrate 102. The anode 104 may be deposited using metal-organic decomposition (MOD). An anode gap 104A separates the anode 104 from an adjacent anode 104.

At operation 404, as shown in FIG. 5B (along the pixel plane), a PIS layer 526 is deposited over the substrate 102. The PIS layer 526 may be deposited on the anode 104 and on the base layer 121 in the anode gap 104A. A height H3 from the base layer 121 to an upper surface 503 of the PIS layer 526 is from about 400 nm to about 700 nm.

At operation 406, as shown in FIG. 5C (along the pixel plane), one or more portions of the PIS layer 526 are removed to form a plurality of first PIS and second PIS. The PIS layer 526 may be removed by a wet etch or dry etch process. Operation 406 exposes the anode 104 and forms the plurality of first PIS 126A and second PIS 126B.

At operation 408, as shown in FIG. 5D (along the pixel plane), the first PIS 126A and second PIS 126B are planarized. The upper surface 103A of the first PIS 126A and the upper surface 103B of the second PIS 126B are aligned with the upper surface of the anode 104. The first PIS 126A and second PIS 126B are cured at a temperature of about 140° C. to about 180° C. for about 10 minutes to about 20 minutes. The curing of the first PIS 126A and second PIS 126B enables shrinkage of the first PIS 126A and second PIS 126B. The first PIS 126A and second PIS 126B are planarized after curing. The planarization process of the first PIS 126A and second PIS 126B may be performed using chemical-mechanical planarization (CMP).

At operation 410, as shown in FIGS. 5E and 5F (along the pixel plane), a first structure layer 510A, a first metal-containing layer 510E of a second structure layer 510B, and a second metal-containing layer of the second structure layer 510B are deposited over the substrate 102. The first structure layer 510A is deposited on the anode 104 and the first PIS 126A and second PIS 126B. The first structure layer 510A has a thickness t₁ from about 0.1 μm to about 0.5 μm.

In an embodiment in which the second structure layer 510B has two layers as shown in FIG. 5E, a first metal-containing layer 510E of second structure layer 510B is deposited on the first structure layer 510A. The first metal-containing layer 510E has a thickness t₂ of about 10 nm to about 30 nm. A second metal-containing layer 510D of second structure layer 510B is deposited on the second layer 510E. The second metal-containing layer 510D has a thickness t₃ from about 150 nm to about 250 nm. The first metal-containing layer 510E is made of a first metal-containing material, e.g., titanium or chromium oxide. The second metal-containing layer 510D is made of a second metal-containing material, e.g., chromium. The first metal-containing layer 510E and second metal-containing layer 510D may be deposited using sputtering deposition.

In another embodiment in which the second structure layer 510B has three layers as shown in FIG. 5F, a third metal-containing layer 510F of second structure layer 510B is deposited on the first structure layer 510A. The third metal-containing layer 510F has a thickness t₂ of about 80 nm to about 120 nm. A first metal-containing layer 510E of the second structure layer 510B is deposited on the third metal-containing layer 510F. The first metal-containing layer 510E has a thickness t₃ of about 10 nm to about 30 nm. A second metal-containing layer 510D is deposited on the second metal-containing layer 510E. The second metal-containing layer 510D has a thickness t₄ from about 80 nm to about 100 nm. The first metal-containing layer 510E is made of a first metal-containing material, e.g., titanium or chromium oxide. The second metal-containing layer 510D and third metal-containing layer 510F are made of a second metal-containing material, e.g., chromium. The third metal-containing layer 510F, first metal-containing layer 510E, and second metal-containing layer 510D are deposited using sputtering deposition.

At operation 412, as shown in FIG. 5G (along the pixel plane), a first resist 506 is disposed and patterned. The resist 506 is disposed over the second structure layer 510B. The resist 506 may have a width W4 of about 0.8 μm to about 1.2 μm. The resist may be a positive resist or a negative resist. A positive resist includes portions of the resist, which, when exposed to electromagnetic radiation, are respectively soluble to a resist developer applied to the resist after the pattern is written into the resist using electromagnetic radiation (e.g., ultraviolet light). A negative resist includes portions of the resist, which, when exposed to radiation, will be respectively insoluble to the resist developer applied to the resist after the pattern is written into the resist using the electromagnetic radiation. The chemical composition of the resist 506 determines whether the resist is a positive resist or a negative resist. The portion of the second structure layer 510B that has the resist 506 disposed thereon is patterned to form a pixel opening 124 of the line-type architecture of a first sub-pixel line 106A. The patterning may be one of a photolithography, digital lithography process, or laser ablation process.

At operation 414, as shown in FIG. 5H (along the pixel plane), portions of the second structure layer 510B and the first structure layer 510A exposed by the pixel opening 124 are removed. The portions of the second structure layer 510B and the first structure layer 510A may be removed using dry etching. Operation 414 forms the second structure 110B, the first structure 110A, and the separation structures 125. The etch selectivity between the metal-containing materials of the second structure layer 510B corresponding to the second structure 110B, the first structure layer 510A corresponding to the first structure 110A, and the etch processes to remove the exposed portions of the second structure layer 510B and the first structure layer 510A provide for the bottom surface 107 of the second structure 110B being wider than the upper surface 105 of the first structure 110A to form an overhang extension 109A of the adjacent overhangs 109. The shadowing of the adjacent overhangs 109 provide for evaporation deposition of the OLE material 112 and the cathode 114.

While the foregoing is directed to embodiments of the present disclosure, other and further embodiments of the disclosure may be devised without departing from the basic scope thereof, and the scope thereof is determined by the claims that follow.

What is claimed is:

1. A sub-pixel, comprising:
adjacent overhang structures disposed over a substrate, wherein the overhang structures define the sub-pixel and comprise:
a second structure disposed over a first structure, wherein the second structure includes a second metal-containing layer disposed over a first metal-containing layer, the second structure including a bottom surface having a second width that is greater than a first width of a top surface of the first structure;
an organic light emitting (OLE) material disposed between the adjacent overhang structures; and
a cathode disposed over the OLE material between the adjacent overhang structures.

2. The sub-pixel of claim 1, wherein the first structure comprises amorphous silicon (a-Si).

3. The sub-pixel of claim 1, wherein:
a first metal-containing material is sputtered to form the first metal-containing layer; and
a second metal-containing material is sputtered to form the second metal-containing layer.

4. The sub-pixel of claim 1, wherein:
the second metal-containing layer comprises chromium; and
the first metal-containing layer comprises at least one of titanium or chromium oxide.

5. The sub-pixel of claim 1, wherein:
the second structure includes a third metal-containing layer, wherein the first metal-containing layer is disposed over the third metal-containing layer.

6. The sub-pixel of claim 5, wherein:
a first metal-containing material is sputtered to form the third metal-containing layer;
a second metal-containing material is sputtered to form the first metal-containing layer; and
the first metal-containing material is sputtered to form the second metal-containing layer.

7. The sub-pixel of claim 5, wherein:
the third metal-containing layer comprises chromium;
the first metal-containing layer comprises at least one of titanium or chromium oxide; and
the second metal-containing layer comprises chromium.

8. A sub-pixel circuit, comprising:
a plurality of overhang structures disposed over a substrate, wherein adjacent overhang structures of the plurality of overhang structures define sub-pixels, each sub-pixel comprising:
adjacent overhang structures, wherein each overhang structure comprises a second structure disposed over a first structure, wherein the second structure includes a second metal-containing layer disposed over a first metal-containing layer, the second structure including a bottom surface having a second width that is greater than a first width of a top surface of the first structure;
an organic light emitting (OLE) material disposed between the adjacent overhang structures; and
a cathode disposed over the OLE material between the adjacent overhang structures.

9. The sub-pixel circuit of claim 8, wherein the first structure comprises amorphous silicon (a-Si).

10. The sub-pixel circuit of claim 8, wherein:
a first metal-containing material is sputtered to form the first metal-containing layer; and
a second metal-containing material is sputtered to form the second metal-containing layer.

11. The sub-pixel circuit of claim 8, wherein:
the second metal-containing layer comprises chromium; and
the first metal-containing layer comprises at least one of titanium or chromium oxide.

12. The sub-pixel circuit of claim 8, wherein:
the second structure includes a third metal-containing layer, wherein the first metal-containing layer is disposed over the third metal-containing layer.

13. The sub-pixel circuit of claim 12, wherein:
a first metal-containing material is sputtered to form the third metal-containing layer;
a second metal-containing material is sputtered to form the second metal-containing layer; and
the first metal-containing material is sputtered to form the first metal-containing layer.

14. The sub-pixel circuit of claim 12, wherein:
the third metal-containing layer comprises chromium;
the first metal-containing layer comprises at least one of titanium or chromium oxide; and
the second metal-containing layer comprises chromium.

15. A method of forming a sub-pixel circuit, comprising:
depositing an anode over a substrate;
depositing a pixel isolation structure (PIS) layer over the substrate;
removing one or more portions of the PIS layer to form a plurality of first PIS and second PIS;
planarizing the first PIS and the second PIS;
depositing a first structure layer, a first metal-containing layer of a second structure layer, and a second metal-containing layer of the second structure layer over the substrate;
disposing and patterning a first resist over the second structure layer; and
removing portions of the second structure layer to form a second structure and portions of the first structure layer to form a first structure.

16. The method of claim 15, wherein:
depositing the first metal-containing layer comprises sputtering a first metal-containing material; and
depositing the second metal-containing layer comprises sputtering a second metal-containing material.

17. The method of claim 15, wherein:
the second metal-containing layer comprises chromium; and
the first metal-containing layer comprises at least one of titanium or chromium oxide.

18. The method of claim 15, wherein:
the second structure includes a third metal-containing layer, wherein the first metal-containing layer is deposited over the third metal-containing layer, and the method further comprising:
depositing the third metal-containing layer over the first structure layer.

19. The method of claim 18, wherein:
depositing the third metal-containing layer comprises sputtering a first metal-containing material;
depositing the first metal-containing layer comprises sputtering a second metal-containing material; and
depositing the second metal-containing layer comprises sputtering the first metal-containing material.

20. The method of claim 18, wherein:
the third metal-containing layer comprises chromium;
the first metal-containing layer comprises at least one of titanium or chromium oxide; and
the second metal-containing layer comprises chromium.
